(19) United States
(12) Patent Application Publication
(10) Pub. No.: US 2013/0143413 A1
(43) Pub. Date: Jun. 6, 2013

(54) WAFER PROCESSING METHOD

(71) Applicant: Disco Corporation, Tokyo (JP)

(72) Inventor: Kazuma SEKIYA, Tokyo (JP)

(73) Assignee: DISCO CORPORATION, Tokyo (JP)

(21) Appl. No.: 13/688,472

(22) Filed: Nov. 29, 2012

(30) Foreign Application Priority Data
Dec. 5, 2011 (JP) 2011-265872

(51) Int. Cl. H01L 21/304

(52) U.S. Cl. CPC H01L 21/304
USPC 438/759

(57) ABSTRACT

The back side of a wafer having a plurality of devices formed on the front side thereof is ground to thereby reduce the thickness of the wafer. A resin layer is formed on the front side of the wafer and is cured. The resin layer is planarized while the back side of the wafer is held on a chuck table and the resin layer formed on the front side of the wafer is exposed. The resin layer is bonded to a hard plate through a bonding member, and the back side of the wafer is ground by using a grinding unit of a grinding apparatus to thereby reduce the thickness of the wafer to a predetermined thickness while the hard plate bonded to the wafer is held on a chuck table of the grinding apparatus.

### BACKGROUND OF THE INVENTION

1. Field of the Invention

The present invention relates to a wafer processing method of grinding the back side of a wafer having a plurality of devices formed on the front side thereof to thereby reduce the thickness of the wafer.

2. Description of the Related Art

In a semiconductor device fabrication process, a plurality of circuit elements such as ICs and CMOSs are formed on the front side of a semiconductor wafer. The back side of the wafer having the circuit elements on the front side thereof is ground by a grinding apparatus to thereby reduce the thickness of the wafer. Thereafter, the wafer is cut into individual chips by using a cutting apparatus, thus obtaining various semiconductor devices. These semiconductor devices thus obtained are widely used in electronic equipment such as mobile phones and PCs (personal computers).

With a recent trend to reduce the size and thickness of electronic equipment, it is required to also reduce the size and thickness of a semiconductor device to be built in the electronic equipment. However, when the wafer is ground to reduce the wafer thickness to 100 μm or less, for example, the rigidity of the wafer is remarkably reduced to cause difficult handling in subsequent steps. In some cases, the wafer may be warped to cause damage to the wafer itself. To solve such problems, there has been widely adopted a technique of bonding a semiconductor wafer to a rigid hard plate in advance and next grinding the wafer to reduce the thickness of the wafer (see Japanese Patent Laid-open No. 2004-207606, for example).

### SUMMARY OF THE INVENTION

However, in bonding the wafer to the hard plate, it is difficult to flatly provide a bonding member such as an adhesive paste and a double-sided adhesive tape on the front side of the wafer due to minute unevenness of the devices formed on the front side of the wafer. As a result, a bonded wafer obtained by bonding the wafer to the hard plate has variations in thickness. Accordingly, even when the back side of the wafer is ground in this condition, the wafer cannot be planarized with high accuracy.

It is therefore an object of the present invention to provide a wafer processing method which can planarize the wafer with high accuracy by grinding.

In accordance with an aspect of the present invention, there is provided a wafer processing method of grinding the back side of a wafer having a plurality of devices formed on the front side thereof to thereby reduce the thickness of the wafer, the wafer processing method including a resin layer forming step of forming a resin layer on the front side of the wafer; a resin layer curing step of curing the resin layer after performing the resin layer forming step; a resin layer planarizing step of planarizing the resin layer in the condition where the back side of the wafer is held on a chuck table and the resin layer formed on the front side of the wafer is exposed after performing the resin layer curing step; a bonding step of bonding the resin layer of the wafer through a bonding member to a hard plate after performing the resin layer planarizing step; and a thickness reducing step of grinding the back side of the wafer by using grinding means of a grinding apparatus to thereby reduce the thickness of the wafer to a predetermined thickness in the condition where the hard plate bonded to the wafer is held on a chuck table of the grinding apparatus after performing the bonding step.

Preferably, the resin layer planarizing step includes the step of cutting the resin layer by using tool cutting means. Preferably, the wafer has a plurality of embedded via electrodes; and the thickness reducing step includes the step of grinding the back side of the wafer until the embedded via electrodes are exposed to the back side of the wafer.

According to the wafer processing method of the present invention, the resin layer formed on the front side of the wafer is bonded through the bonding member to the hard plate in the condition where the resin layer is planarized. Accordingly, a highly accurately flat bonded wafer composed of the wafer and the hard plate can be formed, so that the wafer can be planarized with high accuracy by grinding the back side of the wafer.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a semiconductor wafer as viewed from the front side thereof;

FIG. 2 is a partially sectional side view showing the resin layer forming step;

FIG. 3 is a partially sectional side view showing the resin layer curing step;

FIG. 4 is a perspective view of a tool cutting apparatus;

FIG. 5 is a partially sectional side view showing a first preferred embodiment of the resin layer planarizing step;

FIG. 6 is a partially sectional side view showing a second preferred embodiment of the resin layer planarizing step;

FIG. 7 is an exploded perspective view showing the bonding step;

FIG. 8 is a perspective view showing the thickness reducing step; and

FIG. 9 is a sectional view of a bonded wafer processed by the thickness reducing step.

### DETAILED DESCRIPTION OF THE PREFERRED EMBODIMENT

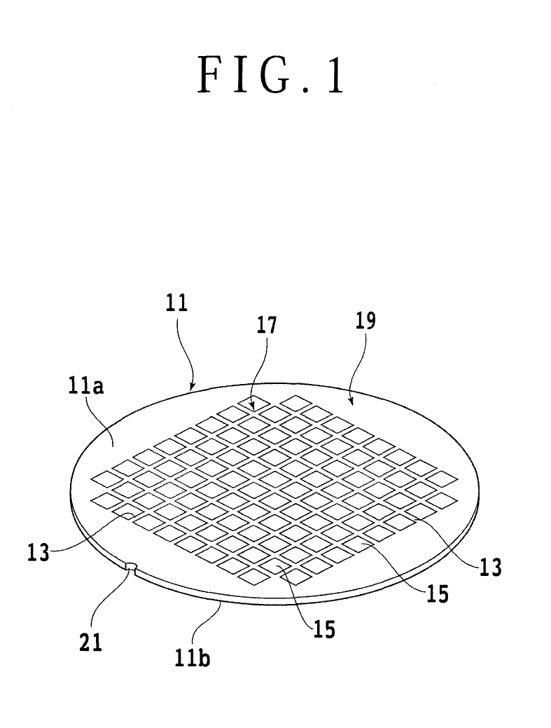

A preferred embodiment of the present invention will now be described in detail with reference to the drawings. FIG. 1 is a perspective view of a semiconductor wafer 11 as viewed from the front side thereof in the condition before the wafer thickness is reduced to a predetermined thickness. The semiconductor wafer 11 shown in FIG. 1 is a silicon wafer having a thickness of 700 μm, for example. The semiconductor wafer 11 has a front side 11a and a back side 11b as shown in FIG. 1. A plurality of crossing streets (division lines) 13 are formed on the front side 11a of the semiconductor wafer 11 to thereby partition a plurality of regions where a plurality of devices 15 such as ICs and LSIs are respectively formed. The front side 11a of the semiconductor wafer 11 is composed of a device area 17 where the devices 15 are formed and a peripheral marginal area 19 surrounding the device area 17. The outer circumference of the semiconductor wafer 11 is formed with a notch 21 as a mark for indicating the crystal orientation of the silicon wafer.

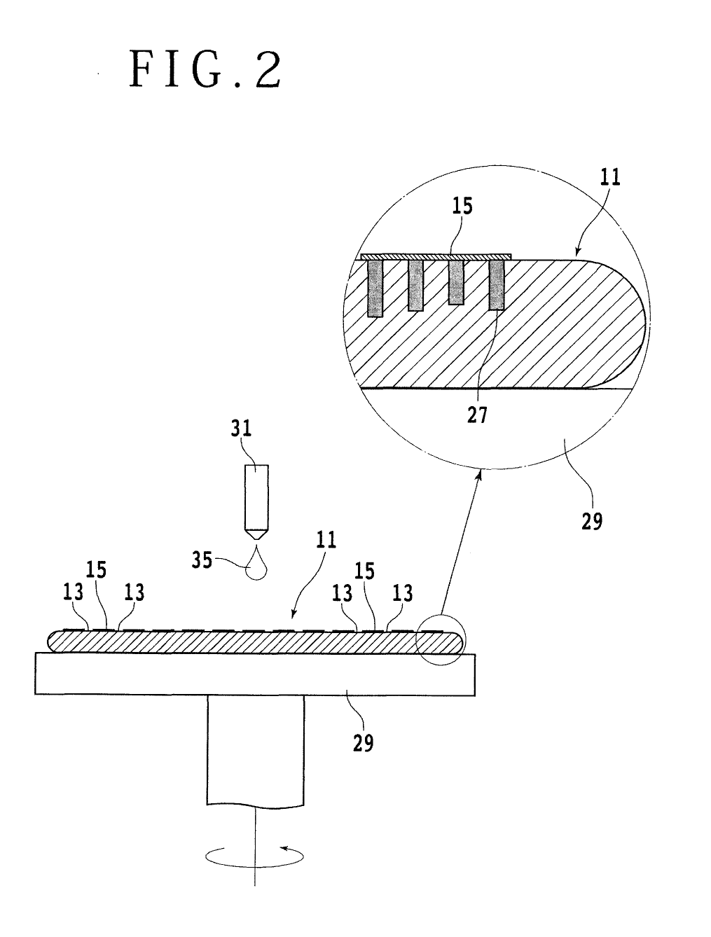

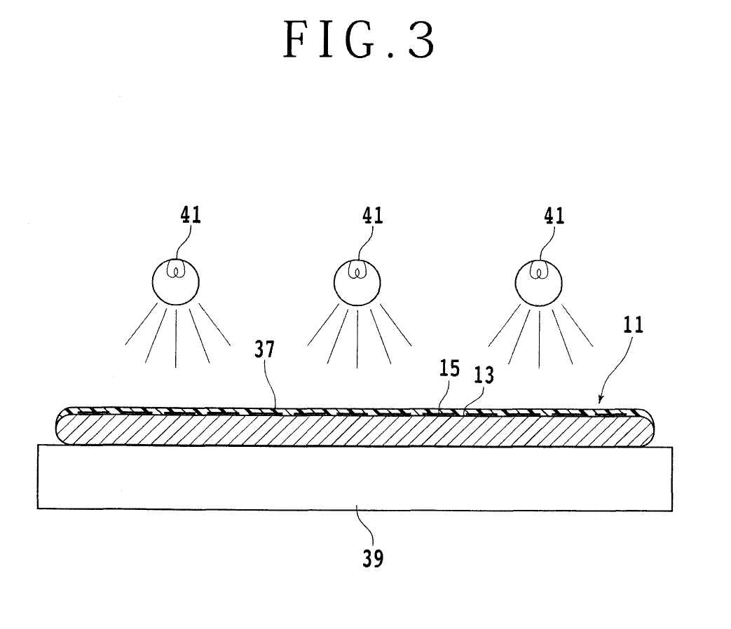

As shown in FIG. 2 in which a part of the semiconductor wafer 11 is enlarged in section in an encircled portion, a plurality of via electrodes 27 are embedded in the semiconductor wafer 11 so as to be connected to electrodes of each device 15. According to the wafer processing method of the present invention, a resin layer forming step is first performed to form a resin layer on the front side 11a of the wafer 11. As shown in FIG. 2, this resin layer forming step is preferably performed by spin coating in such a manner that a holding table 29 holding the wafer 11 is rotated and a resin 35 is dropped from a resin supply nozzle 31 onto the front side 11a of the wafer 11 to thereby form a resin layer 37 on the front side 11a of the wafer 11 as shown in FIG. 3. The resin 35 is preferably selected from an ultraviolet (UV) curing resin and a thermosetting resin. The forming method for the resin layer 37 is not limited to the spin coating mentioned above, but any other suitable methods may be adopted. For example, a high-pressure press may be used to form the resin layer 37 on the front side 11a of the wafer 11. Further, the wafer 11 may be a usual semiconductor wafer not having the embedded via electrodes 27.

After performing the resin layer forming step, a resin layer curing step is performed to cure the resin layer 37 formed on the front side 11a of the wafer 11. In the case that a UV curing resin is used as the resin 35, the resin layer 37 is cured by applying ultraviolet light from UV lamps 41 to the resin layer 37 as shown in FIG. 3. In the case that a thermosetting resin is used as the resin 35, the resin layer 37 is cured by heating the wafer 11 to the curing temperature of the thermosetting resin.

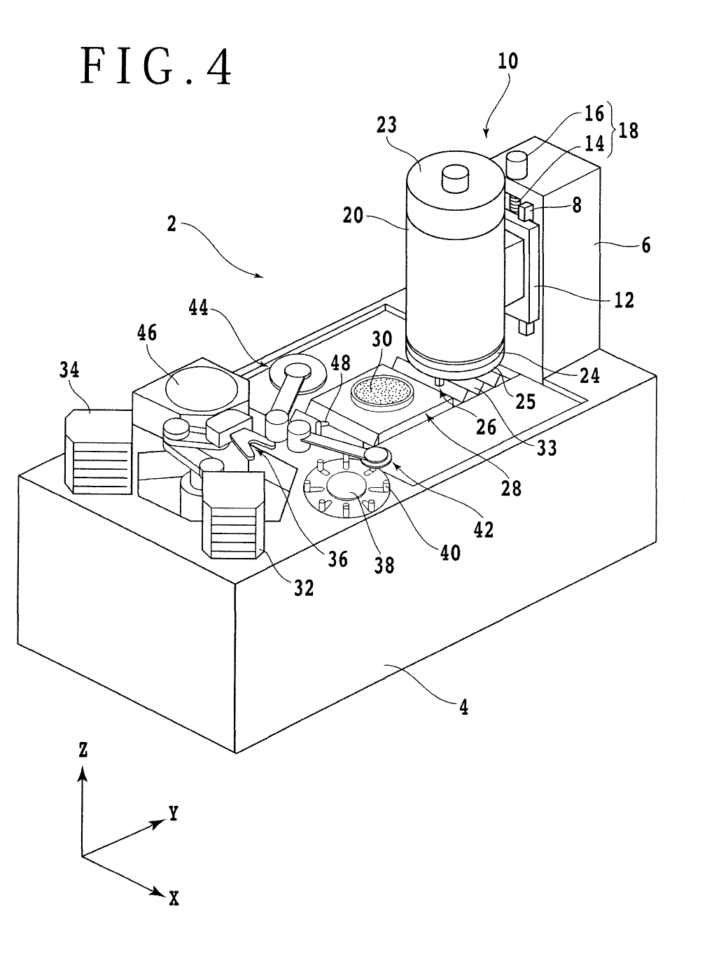

After performing the resin layer curing step, a resin layer planarizing step is performed to planarize the resin layer 37. A first preferred embodiment of the resin layer planarizing step is performed by using a tool cutting apparatus 2 shown in FIG. 4. In FIG. 4, reference numeral 4 denotes a base (housing) of the tool cutting apparatus 2. A column 6 stands on the upper surface of the base 4 at a rear portion thereof. A pair of vertically extending guide rails (one of which being shown) 8 are fixed to the column 6. A tool cutting unit 10 is mounted on the column 6 so as to be vertically movable along the guide rails 8. The tool cutting unit 10 has a housing 20 and a moving support 12 for supporting the housing 20, wherein the moving support 12 is vertically movable along the guide rails 8.

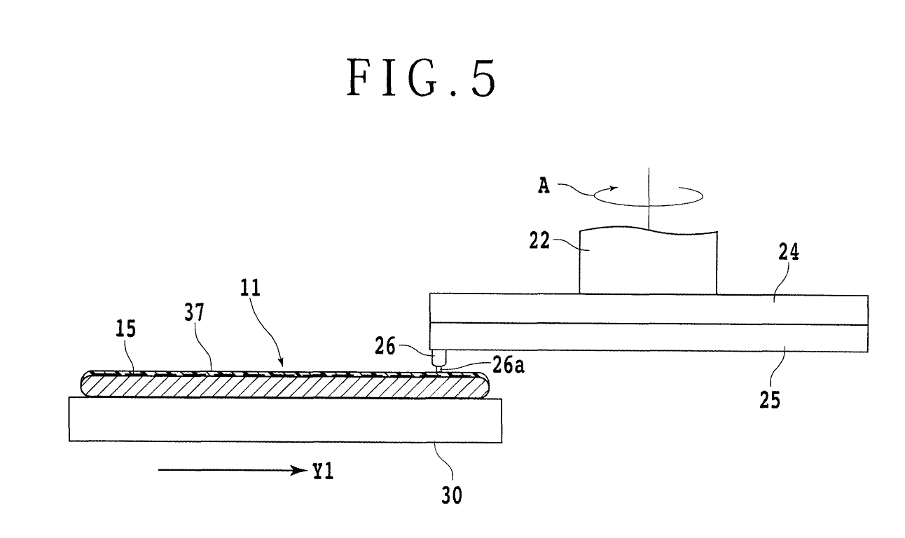

The tool cutting unit 10 includes the housing 20, a spindle 22 (see FIG. 5) rotatably accommodated in the housing 20, a mount 24 fixed to the tip end of the spindle 22, a tool wheel 25 detachably mounted on the lower surface of the mount 24, and a motor 23 for rotationally driving the spindle 22. The tool wheel 25 is provided with a detachable cutting tool 26. The tool cutting unit 10 is vertically moved along the guide rails 8 by a tool cutting unit feeding mechanism 18 including a ball screw 14 and a pulse motor 16. That is, when the pulse motor 16 is operated, the ball screw 14 is rotated to thereby vertically move the moving support 12, thus vertically moving the tool cutting unit 10.

A chuck table mechanism 28 having a chuck table 30 is provided on the upper surface of the base 4 at an intermediate portion thereof. The chuck table mechanism 28 is movable in the Y direction by a chuck table moving mechanism (not shown). A bellows 33 is provided to cover the chuck table mechanism 28. There are further provided on the upper surface of the base 4 at a front portion thereof a first wafer cassette 32, a second wafer cassette 34, a wafer transfer robot 36, a positioning mechanism 38 having a plurality of positioning pins 40, a wafer loading mechanism (loading arm) 42, a wafer unloading mechanism (unloading arm) 44, and a spinner cleaning unit 46.

Further, a cleaning water nozzle 48 for cleaning the chuck table 30 is provided at a substantially central portion of the base 4. When the chuck table 30 is moved to a front position as a wafer loading/unloading position as shown in FIG. 4, the cleaning water nozzle 48 is operated to inject a cleaning water toward the chuck table 30.

The resin layer planarizing step using the tool cutting apparatus 2 shown in FIG. 4 will now be described with reference to FIG. 5. As shown in FIG. 5, the cutting tool 26 is provided with a cutting tip 26a for cutting the resin layer 37. The spindle 22 is rotated in the direction shown by an arrow A in FIG. 5 at a rotational speed of about 2000 rpm, for example, and the tool cutting unit feeding mechanism 18 is operated to feed the tool cutting unit 10, thereby bringing the cutting tip 26a of the cutting tool 26 into contact with the resin layer 37 and then making the cutting tip 26a cut into the resin layer 37 by a predetermined amount. At the same time, the chuck table 30 is moved in the direction shown by an arrow Y1 in FIG. 5 at a feed speed of 1 mm/s, for example, thereby cutting the resin layer 37. In this cutting operation, the chuck table 30 is not rotated, but only fed in the Y1 direction.

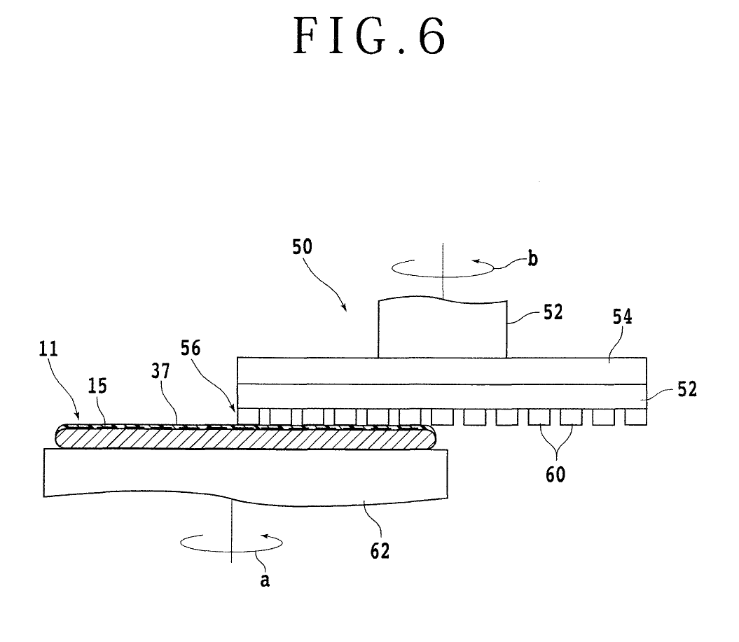

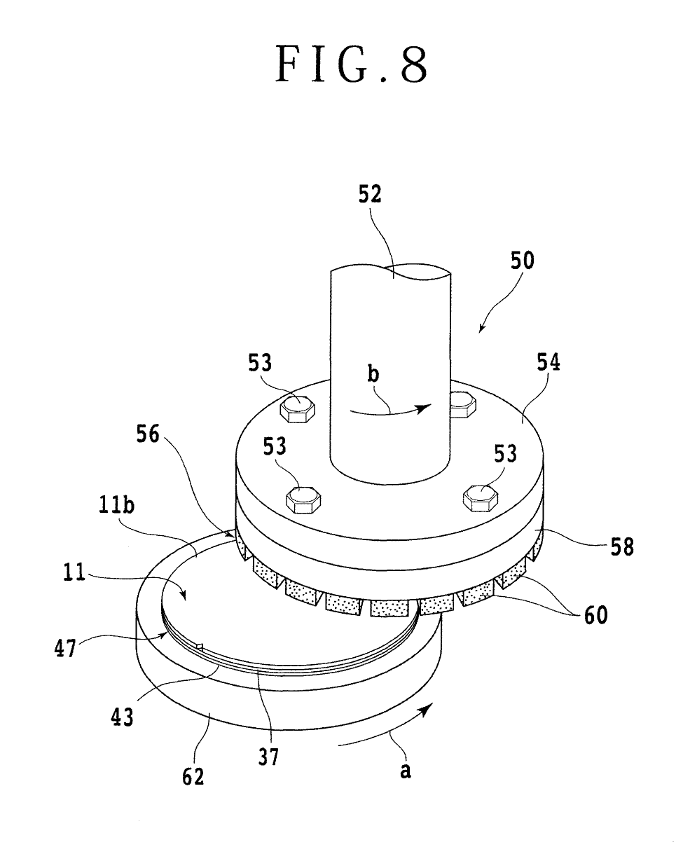

A second preferred embodiment of the resin layer planarizing step is performed by using a grinding apparatus having a grinding unit 50 shown in FIG. 6. That is, the resin layer 37 is ground to be planarized by the grinding unit 50. Referring to FIG. 6, the grinding unit 50 includes a spindle 52, a wheel mount 54 fixed to the tip end of the spindle 52, and a grinding wheel 56 detachably mounted on the lower surface of the wheel mount 54 by a plurality of screws 53 (see FIG. 8). The grinding wheel 56 is composed of an annular wheel base 58 and a plurality of abrasive members 60 fixed to the free end (lower surface) of the wheel base 58.

The resin layer planarizing step using the grinding apparatus having the grinding unit 50 shown in FIG. 6 is performed in the following manner. The grinding apparatus includes a chuck table 62 for holding the wafer 11 under suction. First, the wafer 11 is held under suction on the chuck table 62 in the condition where the back side 11b of the wafer 11 comes into contact with the chuck table 62, that is, the resin layer 37 is exposed. The chuck table 62 thus holding the wafer 11 is set in position so that the resin layer 37 is opposed to the grinding wheel 56 of the grinding unit 50 as shown in FIG. 6. In this condition, the chuck table 62 is rotated at 300 rpm, for example, in the direction shown by an arrow a in FIG. 6, and the grinding wheel 56 is also rotated at 6000 rpm, for example, in the direction shown by an arrow b in FIG. 6. Further, a grinding unit feeding mechanism (not shown) for feeding the grinding unit 50 is operated to bring the abrasive members 60 into contact with the resin layer 37 formed on the front side 11a of the wafer 11 and then feed the grinding wheel 56 at a predetermined feed speed by a predetermined amount, thereby grinding the resin layer 37 to be planarized.

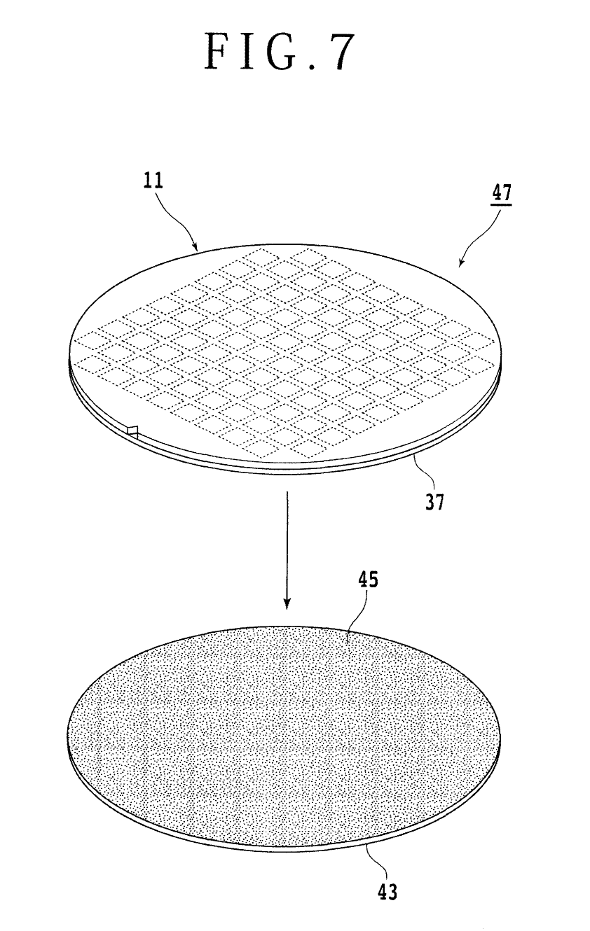

After performing the resin layer planarizing step, a bonding step is performed in such a manner that the resin layer 37 of the wafer 11 is bonded through an adhesive 45 to a hard plate 43 formed of glass or the like as shown in FIG. 7. By performing the bonding step, the resin layer 37 formed on the front side 11a of the wafer 11 and planarized is bonded through the adhesive 45 to the hard plate 43, so that a highly accurately flat bonded wafer 47 can be formed. While an adhesive paste is used as the adhesive 45 in this preferred embodiment, any other suitable bonding members including an adhesive sheet such as a double-sided adhesive tape may be used to bond the resin layer 37 to the hard plate 43. While the hard plate 43 is formed of glass in this preferred embodiment, it may be formed of any other suitable rigid materials including silicon, metal, ceramics, and synthetic resin.

After performing the bonding step, a thickness reducing step is performed by grinding the back side 11b of the wafer 11 bonded to the hard plate 43 to thereby reduce the thickness of the wafer 11 to a predetermined thickness. This thickness reducing step is performed by using the grinding apparatus having the grinding unit 50 as shown in FIG. 8. First, the bonded wafer 47 obtained by bonding the wafer 11 to the hard plate 43 is held under suction on the chuck table 62 in the condition where the hard plate 43 comes into contact with the chuck table 62, that is, the back side 11b of the wafer 11 is exposed. In this condition, the chuck table 62 is rotated at 300 rpm, for example, in the direction shown by an arrow a in FIG. 8 and the grinding wheel 56 is also rotated at 6000 rpm, for example, in the direction shown by an arrow b in FIG. 8. Further, the grinding unit feeding mechanism (not shown) is operated to bring the abrasive members 60 into contact with the back side 11b of the wafer 11.

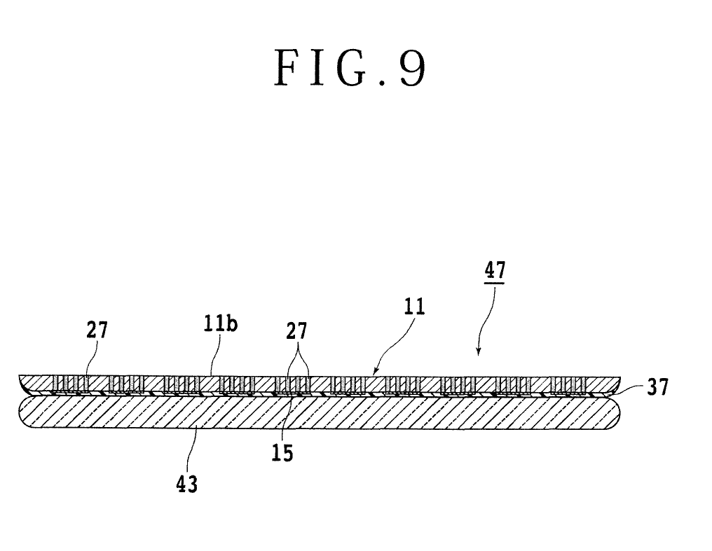

The grinding wheel 56 is further fed downward at a predetermined feed speed by a predetermined amount to grind the back side 11b of the wafer 11. In this grinding operation, the thickness of the wafer 11 is measured by using a contact or noncontact type thickness gauge and is reduced to a predetermined thickness until the via electrodes 27 are exposed to the back side 11b of the wafer 11 as shown in FIG. 9. FIG. 9 is a sectional view of the bonded wafer 47 processed by the thickness reducing step mentioned above.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A wafer processing method of grinding a back side of a wafer having a plurality of devices formed on a front side thereof to thereby reduce the thickness of said wafer, said wafer processing method comprising:
a resin layer forming step of forming a resin layer on the front side of said wafer;
a resin layer curing step of curing said resin layer after performing said resin layer forming step;
a resin layer planarizing step of planarizing said resin layer in a condition where the back side of said wafer is held on a chuck table and said resin layer formed on the front side of said wafer is exposed after performing said resin layer curing step;
a bonding step of bonding said resin layer of said wafer through a bonding member to a hard plate after performing said resin layer planarizing step; and
a thickness reducing step of grinding the back side of said wafer by using grinding means of a grinding apparatus to thereby reduce the thickness of said wafer to a predetermined thickness in a condition where said hard plate bonded to said wafer is held on a chuck table of said grinding apparatus after performing said bonding step.

2. The wafer processing method according to claim 1, wherein said resin layer planarizing step includes the step of cutting said resin layer by using tool cutting means.

3. The wafer processing method according to claim 1, wherein said wafer has a plurality of embedded via electrodes; and
said thickness reducing step includes the step of grinding the back side of said wafer until said embedded via electrodes are exposed to the back side of said wafer.
